(19) United States
(12) Patent Application Publication
(10) Pub. No.: US 2013/0323913 A1
(43) Pub. Date: Dec. 5, 2013

(54) DICHALCOGENOBENZODIPYRROLE COMPOUND

(71) Applicant: Yasuo Miyata, Yokohama-shi (JP)

(72) Inventors: Yasuo Miyata, Yokohama-shi (JP); Mitsuhiro Matsumoto, Toyonaka-shi (JP)

(73) Assignee: SUMITOMO CHEMICAL COMPANY, LIMITED, Chuo-ku, Tokyo (JP)

(21) Appl. No.: 13/981,471

(22) PCT Filed: Feb. 3, 2012
(86) PCT No.: PCT/JP2012/053031

§ 371 Date: Aug. 22, 2013

(30) Foreign Application Priority Data
Feb. 10, 2011 (JP) 2011-026888

(51) Int. Cl. H01L 51/00

(52) U.S. Cl. CPC H01L 51/0071; H01L 51/0007
USPC 438/479; 548/418; 252/500; 438/478

(57) ABSTRACT

A dichalcogenobenzodipyrrole compound represented by the formula (1):

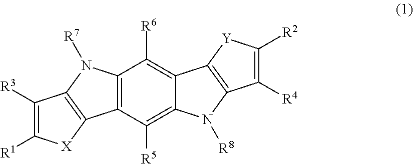

(wherein, X and Y represent each independently a sulfur atom, an oxygen atom, a selenium atom, a tellurium atom or SO₂. R¹ to R⁸ represent each independently a hydrogen atom, a halogen atom, an alkyl group having 1 to 30 carbon atoms, an alkoxy group having 1 to 30 carbon atoms, an alkenyl group having 2 to 30 carbon atoms, an alkynyl group having 2 to 30 carbon atoms, an alkylthio group having 1 to 30 carbon atoms, an aryl group having 6 to 30 carbon atoms or a heteroaryl group having 4 to 30 carbon atoms and the like.) is utilizable in an organic semiconductor device having high carrier mobility.

### TECHNICAL FIELD

The present invention relates to a dichalcogenobenzodipyrrole compound, a process for producing the compound, a film containing the compound, an organic semiconductor device containing the film, and the like.

### BACKGROUND ART

An organic semiconductor device such as an organic transistor containing a film which is obtained by dissolving an organic compound in an organic solvent, coating the resultant composition in the form of a solution on an electrode and the like and drying the organic solvent in the composition is known to sometimes have a semiconductor property such as carrier mobility and the like. For example, JP-A No. 2009-99658, Example 14 describes that a solution prepared by dissolving a compound represented by the following formula:

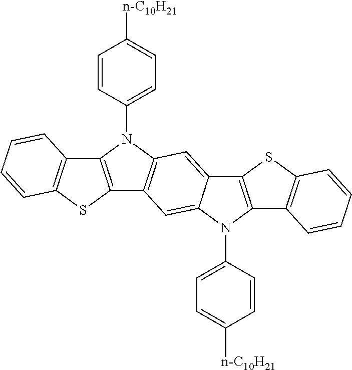

in chlorobenzene is coated on a gate electrode and chlorobenzene is dried to obtain a film and that an organic transistor containing this film has a carrier mobility of 7.4×10⁻² (cm²/V·s).

However, an organic semiconductor device having further improved carrier mobility has been desired.

### SUMMARY OF THE INVENTION

The present invention is as described below.

<1> A dichalcogenobenzodipyrrole compound represented by the formula (1):

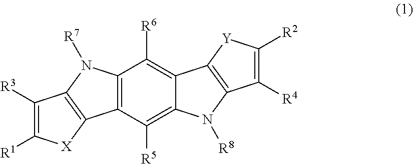

(wherein, X and Y represent each independently a sulfur atom, an oxygen atom, a selenium atom, a tellurium atom or SO₂. R¹ to R⁸ represent each independently a hydrogen atom, a halogen atom, an alkyl group having 1 to 30 carbon atoms optionally substituted by a fluorine atom, an alkoxy group having 1 to 30 carbon atoms optionally substituted by a fluorine atom, an alkenyl group having 2 to 30 carbon atoms optionally substituted by a fluorine atom, an alkynyl group having 2 to 30 carbon atoms optionally substituted by a fluorine atom, an alkylthio group having 1 to 30 carbon atoms optionally substituted by a fluorine atom, an aryl group having 6 to 30 carbon atoms or a heteroaryl group having 4 to 30 carbon atoms. The aryl group and the heteroaryl group may have at least one selected from the group consisting of a fluorine atom, alkyl groups optionally substituted by a fluorine atom, alkoxy groups optionally substituted by a fluorine atom, alkenyl groups optionally substituted by a fluorine atom, alkynyl groups optionally substituted by a fluorine atom and alkylthio groups optionally substituted by a fluorine atom.).

<2> The dichalcogenobenzodipyrrole compound according to <1>, wherein X and Y are a sulfur atom in the above-described formula (1).

<3> The dichalcogenobenzodipyrrole compound according to <1> or <2>, wherein R³ and R⁴ are a hydrogen atom or a halogen atom and R⁷ and R⁸ are an alkyl group having 1 to 30 carbon atoms, an aryl group having 7 to 30 carbon atoms or a heteroaryl group having 5 to 30 carbon atoms (The aryl group and the heteroaryl group have an alkyl group optionally substituted by a fluorine atom or an alkoxy group optionally substituted by a fluorine atom.) in the above-described formula (1).

<4> The dichalcogenobenzodipyrrole compound according to any one of <1> to <3>, wherein R⁵ and R⁶ are a hydrogen atom in the above-described formula (1).

<5> The dichalcogenobenzodipyrrole compound according to any one of <1> to <4>, wherein R¹ to R⁴ are a hydrogen atom or a halogen atom in the above-described formula (1).

<6> The dichalcogenobenzodipyrrole compound according to any one of <1> to <5>, wherein R⁷ and R⁸ are an aryl group having 7 to 26 carbon atoms having an alkyl group optionally substituted by a fluorine atom in the above-described formula (1).

<7> The dichalcogenobenzodipyrrole compound according to any one of <1> to <6>, wherein R⁷ and R⁸ are an alkyl group having 1 to 20 carbon atoms optionally substituted by a fluorine atom in the above-described formula (1).

<8> A film containing the dichalcogenobenzodipyrrole compound according to any one of <1> to <7>.

<9> A film composed of the dichalcogenobenzodipyrrole compound according to any one of <1> to <7>.

<10> An organic transistor containing the film according to <8> or <9>.

<11> An organic semiconductor device containing the film according to <8> or <9>.

<12> A process comprising a step of reacting a compound represented by the formula (2):

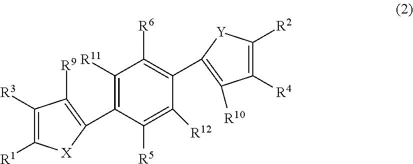

(wherein, X and Y represent each independently a sulfur atom, an oxygen atom, a selenium atom, a tellurium atom or SO₂. R¹ to R⁶ represent each independently a hydrogen atom, a halogen atom, an alkyl group having 1 to 30 carbon atoms optionally substituted by a fluorine atom, an alkoxy group having 1 to 30 carbon atoms optionally substituted by a fluorine atom, an alkenyl group having 2 to 30 carbon atoms optionally substituted by a fluorine atom, an alkynyl group having 2 to 30 carbon atoms optionally substituted by a fluorine atom, an alkylthio group having 1 to 30 carbon atoms optionally substituted by a fluorine atom, an aryl group having 6 to 30 carbon atoms or a heteroaryl group having 4 to 30 carbon atoms. The aryl group and the heteroaryl group may have at least one selected from the group consisting of a fluorine atom, alkyl groups optionally substituted by a fluorine atom, alkoxy groups optionally substituted by a fluorine atom, alkenyl groups optionally substituted by a fluorine atom, alkynyl groups optionally substituted by a fluorine atom and alkylthio groups optionally substituted by a fluorine atom. R⁹ to R¹² represent each independently a halogen atom.)
and an amine compound represented by the formula (3):

R⁷—NH₂ (3)

(wherein, R⁷ represents a hydrogen atom, a halogen atom, an alkyl group having 1 to 30 carbon atoms optionally substituted by a fluorine atom, an alkoxy group having 1 to 30 carbon atoms optionally substituted by a fluorine atom, an alkenyl group having 2 to 30 carbon atoms optionally substituted by a fluorine atom, an alkynyl group having 2 to 30 carbon atoms optionally substituted by a fluorine atom, an alkylthio group having 1 to 30 carbon atoms optionally substituted by a fluorine atom, an aryl group having 6 to 30 carbon atoms or a heteroaryl group having 4 to 30 carbon atoms. The aryl group and the heteroaryl group may have at least one selected from the group consisting of a fluorine atom, alkyl groups optionally substituted by a fluorine atom, alkoxy groups optionally substituted by a fluorine atom, alkenyl groups optionally substituted by a fluorine atom, alkynyl groups optionally substituted by a fluorine atom and alkylthio groups optionally substituted by a fluorine atom.) to produce a dichalcogenobenzodipyrrole compound represented by the formula (1′):

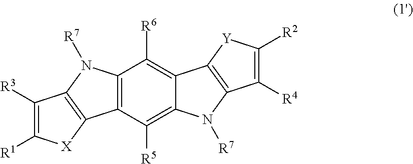

(wherein, X, Y, R¹ to R⁷ are as described above.).

<13> A composition containing the dichalcogenobenzodipyrrole compound according to any one of <1> to <7> and an organic solvent.

<14> A process for producing a film, comprising a step of coating the composition according to <13> on a substrate or an insulation layer and a step of drying the coated film coated on the substrate or insulation layer.

### BRIEF EXPLANATION OF DRAWINGS

FIG. 1 is a sectional view illustrating one embodiment of an organic transistor in the present invention.

FIG. 2 is a sectional view illustrating one embodiment of an organic transistor in the present invention.

The number 11 represents a substrate, 12 represents a gate electrode, 13 represents a gate insulation film, 14 represents a source electrode, 15 represents a drain electrode and 16 represents an organic semiconductor layer. The number 21 represents a substrate, 22 represents a source electrode, 23 represents a drain electrode, 24 represents a gate insulation film, 25 represents a gate electrode and 26 represents an organic semiconductor layer.

### MODES FOR CARRYING OUT THE INVENTION

The present invention provides a dichalcogenobenzodipyrrole compound represented by the formula (1):

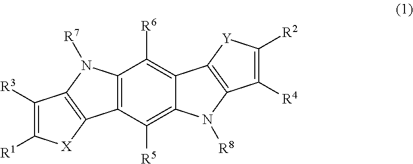

(“compound (1)”).

In the compound (1), X and Y represent each independently a sulfur atom, an oxygen atom, a selenium atom, a tellurium atom or SO₂.

Since synthesis of the compound (1) is easy when X and Y are identical in the compound (1), it is preferable that X and Y are identical in the compound (1) and it is more preferable that both X and Y are a sulfur atom.

R¹ to R⁸ represent each independently a hydrogen atom, a halogen atom, an alkyl group having 1 to 30 carbon atoms optionally substituted by a fluorine atom, an alkoxy group having 1 to 30 carbon atoms optionally substituted by a fluorine atom, an alkenyl group having 2 to 30 carbon atoms optionally substituted by a fluorine atom, an alkynyl group having 2 to 30 carbon atoms optionally substituted by a fluorine atom, an alkylthio group having 1 to 30 carbon atoms optionally substituted by a fluorine atom, an aryl group having 6 to 30 carbon atoms, a heteroaryl group having 4 to 30 carbon atoms. The aryl group and the heteroaryl group may have at least one selected from the group consisting of a fluorine atom, alkyl groups optionally substituted by a fluorine atom, alkoxy groups optionally substituted by a fluorine atom, alkenyl groups optionally substituted by a fluorine atom, alkynyl groups optionally substituted by a fluorine atom and alkylthio groups optionally substituted by a fluorine atom.

It is preferable that R¹ to R⁴ are a hydrogen atom or a halogen atom such as a fluorine atom or the like.

The alkyl group having 1 to 30 carbon atoms in the present invention may be any of linear, branched and cyclic. R¹ to R⁸ may also be an alkyl group in which part or all of hydrogen atoms in them are substituted by a fluorine atom.

The alkyl group includes, for example, linear alkyl groups such as a methyl group, an ethyl group, a n-propyl group, a n-butyl group, a n-pentyl group, a n-hexyl group, a n-heptyl group, a n-octyl group, a n-nonyl group, a n-decyl group, a n-undecyl group, a n-dodecyl group, a n-tridecyl group, a n-tetradecyl group, a n-pentadecyl group, a n-hexadecyl group, a n-heptadecyl group, a n-octadecyl group, a n-nonadecyl group, a n-icosyl group, a n-henicosyl group, a n-docosyl group, a n-tricosyl group, a n-tetracosyl group, a n-pentacosyl group, a n-hexacosyl group, a n-heptacosyl group, a n-octacosyl group, a n-nonacosyl group, a n-triacontyl group and the like; branched alkyl groups such as an isopropyl group, a s-butyl group, a t-butyl group, a neopentyl group, a 2-ethylhexyl group, a 2-hexyldecyl group and the like; and cyclic alkyl groups such as a cyclopentyl group, a cyclohexyl group, a cyclooctyl group and the like.

Preferable are alkyl groups having 1 to 20 carbon atoms such as a methyl group, an ethyl group, a n-propyl group, an isopropyl group, a n-butyl group, a s-butyl group, a t-butyl group, a n-pentyl group, a neopentyl group, a n-hexyl group, a 2-ethylhexyl group, a cyclohexyl group, a n-heptyl group, a n-octyl group, a cyclooctyl group, a n-nonyl group, a n-decyl group, a 2-hexyldecyl group, a n-undecyl group, a n-dodecyl group, a n-tridecyl group, a n-tetradecyl group, a n-pentadecyl group, a n-hexadecyl group, a n-heptadecyl group, a n-octadecyl group, a n-nonadecyl group, a n-icosyl group and the like, and those obtained by substituting part or all of hydrogen atoms in them by a fluorine atom are also preferable. More preferable are alkyl groups having 2 to 16 carbon atoms such as an ethyl group, a n-propyl group, a n-butyl group, a n-pentyl group, a n-hexyl group, a 2-ethylhexyl group, a cyclohexyl group, a n-heptyl group, a n-octyl group, a n-nonyl group, a n-decyl group, a 2-hexyldecyl group, a n-undecyl group, a n-dodecyl group, a n-tridecyl group, a 2-hexyloctyl group, a n-tetradecyl group, a n-pentadecyl group, a n-hexadecyl group and the like, and those obtained by substituting part or all of hydrogen atoms in them by a fluorine atom are also preferable.

The alkoxy group having 1 to 30 carbon atoms in the present invention may be any of linear, branched and cyclic. R¹ to R⁸ may also be an alkoxy group in which part or all of hydrogen atoms in them are substituted by a fluorine atom.

The alkoxy group includes, for example, linear alkoxy groups such as a methoxy group, an ethoxy group, a n-propoxy group, a n-butoxy group, a n-pentyloxy group, a n-hexyloxy group, a n-heptyloxy group, a n-octyloxy group, a n-decyloxy group, a n-undecyloxy group, a n-dodecyloxy group, a n-tridecyloxy group, a n-tetradecyloxy group, a n-pentadecyloxy group, a n-hexadecyloxy group, a n-nonyloxy group, a n-heptadecyloxy group, a n-octadecyloxy group, a n-nonadecyloxy group, a n-icosyloxy group, a n-henicosyloxy group, a n-docosyloxy group, a n-tricosyloxy group, a n-tetracosyloxy group, a n-pentacosyloxy group, a n-hexacosyloxy group, a n-heptacosyloxy group, a n-octacosyloxy group, a n-nonacosyloxy group, a n-triacontyloxy group and the like; branched alkoxy groups such as an isopropoxy group, a s-butoxy group, a t-butoxy group, a neopentyloxy group, a 2-ethylhexyloxy group, a 2-hexyldecyloxy group, a 3,7-dimethyloctyloxy group and the like; cyclic alkoxy groups such as a cyclohexyloxy group, a cyclooctyloxy group and the like; and a methoxymethoxy group, a methoxyethoxy group, a methoxymethoxymethoxy group, a methoxyethoxyethoxy group and a polyethyleneglycoxy group.

Preferable are alkoxy groups having 1 to 20 carbon atoms such as a methoxy group, an ethoxy group, a n-propoxy group, an isopropoxy group, a n-butoxy group, a s-butoxy group, a t-butoxy group, a n-pentyloxy group, a n-hexyloxy group, a 2-ethylhexyloxy group, a cyclohexyloxy group, a n-heptyloxy group, a n-octyloxy group, a cyclooctyloxy group, a n-nonyloxy group, a n-decyloxy group, a 2-hexyldecyloxy group, a 3,7-dimethyloctyloxy group, a n-undecyloxy group, a n-dodecyloxy group, a n-tridecyloxy group, a n-tetradecyloxy group, a n-pentadecyloxy group, a n-heptadecyloxy group, a n-octadecyloxy group, a n-nonadecyloxy group, a n-icosyloxy group, a methoxymethoxy group, a methoxyethoxy group, a methoxymethoxymethoxy group, a methoxyethoxyethoxy group and the like, and those obtained by substituting part or all of hydrogen atoms in them by a fluorine atom are also preferable. More preferable are alkoxy groups having 1 to 16 carbon atoms such as an ethoxy group, a n-propoxy group, a n-butoxy group, a n-pentyloxy group, a n-hexyloxy group, a 2-ethylhexyloxy group, a cyclohexyloxy group, a n-heptyloxy group, a n-octyloxy group, a n-nonyloxy group, a n-decyloxy group, a 2-hexyldecyloxy group, a n-undecyloxy group, a n-dodecyloxy group, a n-tridecyloxy group, a n-tetradecyloxy group, a n-pentadecyloxy group, a n-hexadecyloxy group, a methoxymethoxy group, a methoxyethoxy group, a methoxymethoxymethoxy group and a methoxyethoxyethoxy group, and those obtained by substituting part or all of hydrogen atoms in them by a fluorine atom are also preferable.

The alkenyl group in the present invention is an alkenyl group having 2 to 30 carbon atoms, and may be any of linear, branched and cyclic. R¹ to R⁸ and R¹³ may also be an alkenyl group in which part or all of hydrogen atoms in them are substituted by a fluorine atom.

The alkenyl group includes, for example, linear alkenyl groups such as an ethenyl group, a 1-propenyl group, a 1-butenyl group, a 1-pentenyl group, a 1-hexenyl group, a 1-heptenyl group, a 1-octenyl group, a 1-nonenyl group, a 1-decenyl group, a 1-undecenyl group, a 1-dodecenyl group, a 1-tridecenyl group, a 1-tetradecenyl group, a 1-pentadecenyl group, a 1-hexadecenyl group, a 1-heptadecenyl group, a 1-octadecenyl group, a 1-nonadecenyl group, a 1-icosenyl group, a 1-henicosenyl group, a 1-docosenyl group, a 1-tricosenyl group, a 1-tetracosenyl group, a 1-pentacosenyl group, a 1-hexacosenyl group, a 1-heptacosenyl group, a 1-octacosenyl group, a 1-nonacosenyl group, a 1-triacontenyl group and the like; branched alkenyl groups such as a 1-methyl-1-propenyl group and the like; and cyclic alkenyl groups such as a 1-cyclohexenyl group and the like. Preferable are alkenyl groups having 2 to 20 carbon atoms such as an ethenyl group, a 1-propenyl group, a 1-butenyl group, a 1-pentenyl group, a 1-hexenyl group, a 1-heptenyl group, a 1-octenyl group, a 1-nonenyl group, a 1-decenyl group, a 1-undecenyl group, a 1-dodecenyl group, a 1-tridecenyl group, a 1-tetradecenyl group, a 1-pentadecenyl group, a 1-hexadecenyl group, a 1-heptadecenyl group, a 1-octadecenyl group, a 1-nonadecenyl group, a 1-icosenyl group and the like, and those obtained by substituting part or all of hydrogen atoms in them by a fluorine atom are also preferable. More preferable are alkenyl groups having 2 to 16 carbon atoms such as an ethenyl group, a 1-propenyl group, a 1-butenyl group, a 1-pentenyl group, a 1-hexenyl group, a 1-heptenyl group, a 1-octenyl group, a 1-nonenyl group, a 1-decenyl group, a 1-undecenyl group, a 1-dodecenyl group, a 1-tridecenyl group, a 1-tetradecenyl group, a 1-pentadecenyl group, a 1-hexadecenyl group and the like, and those obtained by substituting part or all of hydrogen atoms in them by a fluorine atom are also preferable.

The alkynyl group having 2 to 30 carbon atoms in the present invention may be any of linear, branched and cyclic. R¹ to R⁸ may also be an alkynyl group in which part or all of hydrogen atoms in them are substituted by a fluorine atom.

The alkynyl group includes, for example, an ethynyl group, a 1-propynyl group, a 1-butynyl group, a 1-pentynyl group, a 1-hexynyl group, a 1-heptynyl group, a 1-octynyl group, a 1-nonynyl group, a 1-decynyl group, a 1-undecyl group, a 1-dodecynyl group, a 1-tridecynyl group, a 1-tetradecynyl group, a 1-pentadecynyl group, a 1-hexadecynyl group, a 1-heptadecynyl group, a 1-octadecynyl group, a 1-nonadecynyl group, a 1-icosynyl group, a 1-henicosynyl group, a 1-docosynyl group, a 1-tricosynyl group, a 1-tetracosynyl group, a 1-pentacosynyl group, a 1-hexacosynyl group, a 1-heptacosynyl group, a 1-octacosynyl group, a 1-nonacosynyl group and a 1-triacontynyl group. Preferable are alkynyl groups having 2 to 20 carbon atoms such as an ethynyl group, a 1-propynyl group, a 1-butynyl group, a 1-pentynyl group, a 1-hexynyl group, a 1-heptynyl group, a 1-octynyl group, a 1-nonynyl group, a 1-decynyl group, a 1-undecynyl group, a 1-dodecynyl group, a 1-tridecynyl group, a 1-tetradecynyl group, a 1-pentadecynyl group, a 1-hexadecynyl group, a 1-heptadecynyl group, a 1-octadecynyl group, a 1-nonadecynyl group, a 1-icosynyl group and the like, and those obtained by substituting part or all of hydrogen atoms in them by a fluorine atom are also preferable. More preferable are alkynyl groups having 2 to 16 carbon atoms such as an ethynyl group, a 1-propynyl group, a 1-butynyl group, a 1-pentynyl group, a 1-hexynyl group, a 1-heptynyl group, a 1-octynyl group, a 1-nonynyl group, a 1-decynyl group, a 1-undecynyl group, a 1-dodecynyl group, a 1-tridecynyl group, a 1-tetradecynyl group, a 1-pentadecynyl group, a 1-hexadecynyl group and the like, and those obtained by substituting part or all of hydrogen atoms in them by a fluorine atom are also preferable.

The alkylthio group having 1 to 30 carbon atoms in the present invention may be any of linear, branched and cyclic. R¹ to R⁸ may also be an alkylthio group in which part or all of hydrogen atoms in them are substituted by a fluorine atom.

The alkylthio group includes, for example, linear alkylthio groups such as a methylthio group, an ethylthio group, a n-propylthio group, an isopropylthio group, a n-butylthio group, a n-pentylthio group, a n-hexylthio group, a n-heptylthio group, a n-octylthio group, a n-nonylthio group, a n-decylthio group, a n-undecylthio group, a n-dodecylthio group, a n-tridecylthio group, a n-tetradecylthio group, a n-pentadecylthio group, a n-hexadecylthio group, a n-heptadecylthio group, a n-octadecylthio group, a n-nonadecylthio group, a n-icosylthio group, a n-henicosylthio group, a n-docosylthio group, a n-tricosylthio group, a n-tetracosylthio group, a n-pentacosylthio group, a n-hexacosylthio group, a n-heptacosylthio group, a n-octacosylthio group, a n-nonacosylthio group, a n-triacontylthio group and the like; branched alkylthio groups such as a s-butylthio group, a t-butylthio group, a neopentylthio group, a 2-ethylhexylthio group, a 2-hexyldecylthio group and the like; and cyclic alkylthio groups such as a cyclopentylthio group, a cyclohexylthio group, a cyclooctylthio group and the like.

Preferable are alkylthio groups having 1 to 20 carbon atoms such as a methylthio group, an ethylthio group, a n-propylthio group, an isopropylthio group, a n-butylthio group, a s-butylthio group, a t-butylthio group, a n-pentylthio group, a neopentylthio group, a n-hexylthio group, a 2-ethylhexylthio group, a cyclohexylthio group, a n-heptylthio group, a n-octylthio group, a cyclooctylthio group, a n-nonylthio group, a n-decylthio group, a 2-hexyldecylthio group, a n-undecylthio group, a n-dodecylthio group, a n-tridecylthio group, a n-tetradecylthio group, a n-pentadecylthio group, a n-hexadecylthio group, a n-heptadecylthio group, a n-octadecylthio group, a n-nonadecylthio group, a n-icosylthio group and the like, and those obtained by substituting part or all of hydrogen atoms in them by a fluorine atom are also preferable. More preferable are alkylthio groups having 1 to 16 carbon atoms such as a methylthio group, an ethylthio group, a n-propylthio group, a n-butylthio group, a n-pentylthio group, a n-hexylthio group, a 2-ethylhexylthio group, a cyclohexylthio group, a n-heptylthio group, a n-octylthio group, a cyclooctylthio group, a n-nonylthio group, a n-decylthio group, a 2-hexyldecylthio group, a n-undecylthio group, a n-dodecylthio group, a n-tridecylthio group, a 2-hexyloctylthio group, a n-tetradecylthio group, a n-pentadecylthio group, a n-hexadecylthio group and the like, and those obtained by substituting part or all of hydrogen atoms in them by a fluorine atom are also preferable.

The aryl group having 6 to 30 carbon atoms in the present invention includes, for example, a phenyl group and a naphthyl group. R¹ to R⁸ may also be an aryl group in which part or all of hydrogen atoms in them are substituted by a fluorine atom.

Further, R¹ to R⁸ may also be an aryl group having at least one selected from the group consisting of alkyl groups substituted by a fluorine atom, alkoxy groups substituted by a fluorine atom, alkenyl groups substituted by a fluorine atom, alkynyl groups substituted by a fluorine atom and alkylthio groups substituted by a fluorine atom. The alkyl group, the alkoxy group, the alkenyl group, the alkynyl group and the alkylthio group are as described above. Regarding the number of carbon atoms of the aryl group having a substituent, the total number of carbon atoms including the substituent is preferably 7 to 30.

Preferable examples of R¹ to R⁸ are aryl groups having an alkyl group or an alkoxy group. Preferable specific examples thereof include phenyl groups having a linear alkyl group having 1 to 24 carbon atoms such as a methylphenyl group, an ethylphenyl group, a n-propylphenyl group, an isopropylphenyl group, a n-butylphenyl group, a n-pentylphenyl group, a n-hexylphenyl group, a n-heptylphenyl group, a n-octylphenyl group, a n-nonylphenyl group, a n-decylphenyl group, a n-undecylphenyl group, a n-dodecylphenyl group, a n-tridecylphenyl group, a n-tetradecylphenyl group and the like; and phenyl groups having a linear alkoxy group having 1 to 24 carbon atoms such as a methoxyphenyl group, an ethoxyphenyl group, a n-propoxyphenyl group, a n-butoxyphenyl group, a n-pentyloxyphenyl group, a n-hexyloxyphenyl group, a n-heptyloxyphenyl group, a n-octyloxyphenyl group, a n-decyloxyphenyl group, a n-undecyloxyphenyl group, a n-dodecyloxyphenyl group, a n-tridecyloxyphenyl group, a n-tetradecyloxyphenyl group and the like.

The heteroaryl group having 4 to 30 carbon atoms in the present invention is, for example, a thiophenylyl group, a furanyl group, a selenophenyl group, a pyrrolyl group, an oxazolyl group, a thiazole group, a pyridinyl group, a pyrazinyl group, a pyrimidinyl group or a pyridazinyl group. R¹ to R⁸ may also be a heteroaryl group in which part or all of hydrogen atoms in them are substituted by a fluorine atom.

Further, R¹ to R⁸ may also be a heteroaryl group having at least one selected from the group consisting of alkyl groups substituted by a fluorine atom, alkoxy groups substituted by a fluorine atom, alkenyl groups substituted by a fluorine atom, alkynyl groups substituted by a fluorine atom and alkylthio groups substituted by a fluorine atom. The alkyl group, the alkoxy group, the alkenyl group, the alkynyl group and the alkylthio group are as described above. Regarding the number of carbon atoms of the heteroaryl group having a substituent, the total number of carbon atoms including the substituent is preferably 7 to 16.

In the present invention, the halogen atom is a fluorine atom, a chlorine atom, a bromine atom or an iodine atom, and the halogen atom represented by R¹ to R⁸ is preferably a fluorine atom.

In the compound (1), R¹ and R² are preferably identical. It is preferable that R¹ and R² are a hydrogen atom or a halogen atom such as a fluorine atom or the like. It is preferable that R³ and R⁴ are identical. It is preferable that R¹ and R² are a hydrogen atom or a halogen atom such as a fluorine atom or the like.

It is preferable that all of R¹ to R⁴ are a hydrogen atom in the compound (1).

It is preferable that both R⁵ and R⁶ are a hydrogen atom in the compound (1).

It is preferable that R⁷ and R⁸ are identical and R⁷ and R⁸ are an aryl group having 7 to 26 carbon atoms in total optionally having an alkyl group substituted by a fluorine atom, in the compound (1).

Preferable specific examples of R⁷ and R⁸ are phenyl groups having a linear alkyl group having 1 to 14 carbon atoms such as a methylphenyl group, an ethylphenyl group, a n-propylphenyl group, an isopropylphenyl group, a n-butylphenyl group, a n-pentylphenyl group, a n-hexylphenyl group, a n-heptylphenyl group, a n-octylphenyl group, a n-nonylphenyl group, a n-decylphenyl group, a n-undecylphenyl group, a n-dodecylphenyl group, a n-tridecylphenyl group, a n-tetradecylphenyl group and the like; and for example, a methoxyphenyl group, an ethoxyphenyl group, a n-propoxyphenyl group, a n-butoxyphenyl group, a n-pentyloxyphenyl group, a n-hexyloxyphenyl group, a n-heptyloxyphenyl group, a n-octyloxyphenyl group, a n-decyloxyphenyl group, a n-undecyloxyphenyl group, a n-dodecyloxyphenyl group, a n-tridecyloxyphenyl group and a n-tetradecyloxyphenyl group.

It is also preferable that R⁷ and R⁸ are identical and R⁷ and R⁸ are an alkyl group having 1 to 20 carbon atoms optionally substituted by a fluorine atom, in the compound (1).

Preferable specific examples of R⁷ and R⁸ are alkyl groups having 1 to 20 carbon atoms such as a methyl group, an ethyl group, a n-propyl group, an isopropyl group, a n-butyl group, a s-butyl group, a t-butyl group, a n-pentyl group, a neopentyl group, a n-hexyl group, a 2-ethylhexyl group, a cyclohexyl group, a n-heptyl group, a n-octyl group, a cyclooctyl group, a n-nonyl group, a n-decyl group, a 2-hexyldecyl group, a n-undecyl group, a n-dodecyl group, a n-tridecyl group, a n-tetradecyl group, a n-pentadecyl group, a n-hexadecyl group, a n-heptadecyl group, a n-octadecyl group, a n-nonadecyl group, a n-icosyl group and the like, and groups obtained by substituting part or all of hydrogen atoms in these groups by a fluorine atom.

Examples of the compound (1) are described in Tables 1 to 8.

TABLE 1

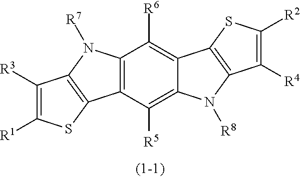

| Compound | R¹ and | R³ and | R⁵ and | |
|---|---|---|---|---|
| number | R² | R⁴ | R⁶ | R⁷ and R⁸ |
| (1-1-1) | H | H | H | H |
| (1-1-2) | H | H | H | CH₂ |
| (1-1-3) | H | H | H | C₂H₅ |
| (1-1-4) | H | H | H | i-C₃H₉ |
| (1-1-5) | H | H | H | n-C₄H₉ |
| (1-1-6) | H | H | H | s-C₄H₉ |
| (1-1-7) | H | H | H | n-C₅H₁₁ |
| (1-1-8) | H | H | H | 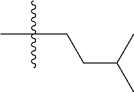 [SMILES: *CCC(C)C] |
| (1-1-9) | H | H | H | n-C₆H₁₃ |
| (1-1-10) | H | H | H | 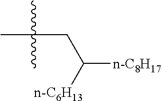 |
| (1-1-11) | H | H | H | n-C₈H₁₇ |
| (1-1-12) | H | H | H | n-C₁₀H₂₁ |
| (1-1-13) | H | H | H | 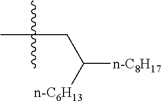 |
| (1-1-14) | H | H | H | n-C₁₂H₂₅ |
| (1-1-15) | H | H | H | n-C₁₆H₃₃ |
| (1-1-16) | H | H | H | n-C₂₀H₄₁ |
| (1-1-17) | H | H | H | n-C₂₅H₅₁ |
| (1-1-18) | H | H | H | n-C₃₀H₆₁ |
| (1-1-19) | H | H | H | n-C₆F₁₃ |
| (1-1-20) | H | H | H | n-C₁₂H₂₅ |

TABLE 2

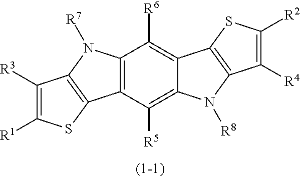

| Compound | R¹ and | R³ and | R⁵ and | |
|---|---|---|---|---|
| number | R² | R⁴ | R⁶ | R⁷ and R⁸ |
| (1-1-21) | H | H | H | 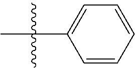 [SMILES: *c1ccccc1] |
| (1-1-22) | H | H | H | 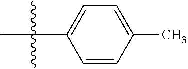 [SMILES: *c1ccc(C)cc1] |
| (1-1-23) | H | H | H | 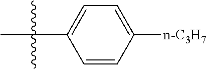 |
| (1-1-24) | H | H | H | 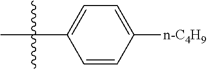 |
| (1-1-25) | H | H | H | 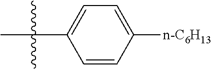 |
| (1-1-26) | H | H | H | 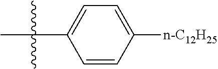 |
| (1-1-27) | H | H | H | 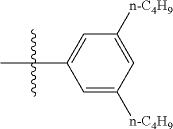 |
| (1-1-28) | H | H | H | 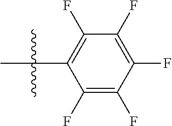 [SMILES: *c1c(F)c(F)c(F)c(F)c1F] |
| (1-1-29) | H | H | H | 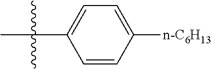 |
| (1-1-30) | H | H | H | 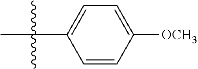 [SMILES: *c1ccc(OC)cc1] |
| (1-1-31) | H | H | H | 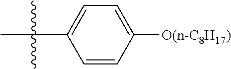 |
| (1-1-32) | H | H | H | 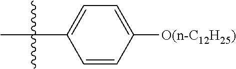 |

TABLE 3

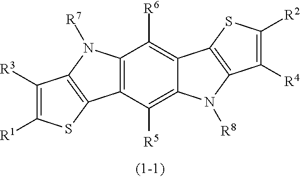

| Compound | | | | |
|---|---|---|---|---|
| number | R¹ and R² | R³ and R⁴ | R⁵ and R⁶ | R⁷ and R⁸ |
| (1-1-33) | H | H | CH₃ | n-C₆H₁₃ |
| (1-1-34) | H | H | C₂H₅ | 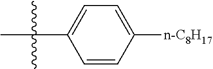 |
| (1-1-35) | H | H | n-C₆H₁₃ | C₂H₅ |
| (1-1-36) | H | H | n-C₁₂H₂₅ | 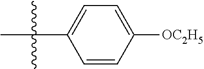 [SMILES: *c1ccc(OCC)cc1] |
| (1-1-37) | H | H | 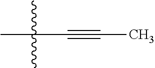 [SMILES: *C#CC] | n-C₉H₁₉ |
| (1-1-38) | H | H | 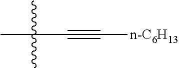 | n-C₄H₉ |
| (1-1-39) | H | H | OCH₃ | n-C₆H₁₃ |
| (1-1-40) | H | H | S (n-C₆H₁₃) | C₂H₅ |
| (1-1-41) | H | H | 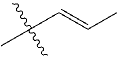 [SMILES: */C=C/C] | n-C₇H₁₅ |
| (1-1-42) | CH₃ | H | H | n-C₆H₁₃ |
| (1-1-43) | n-C₄H₉ | H | H | n-C₄H₉ |
| (1-1-44) | 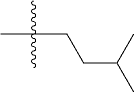 [SMILES: *CCC(C)C] | H | CH₃ | 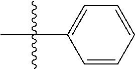 [SMILES: *c1ccccc1] |
| (1-1-45) | n-C₆H₁₃ | H | H | 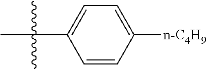 |
| (1-1-46) | n-C₈H₁₇ | H | H | 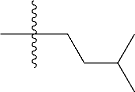 [SMILES: *CCC(C)C] |
| (1-1-47) | 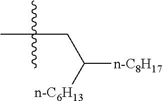 | H | H | 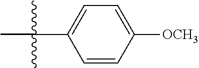 [SMILES: *c1ccc(OC)cc1] |
| (1-1-48) | n-C₁₂H₂₅ | H | H | i-C₃H₉ |
| (1-1-49) | n-C₂₀H₄₁ | H | 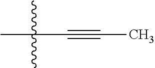 [SMILES: *C#CC] | 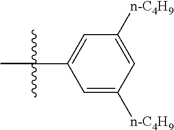 |
| (1-1-50) | 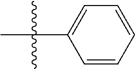 [SMILES: *c1ccccc1] | H | H | n-C₅H₁₁ |
| (1-1-51) | 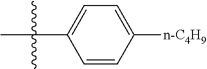 | H | H | 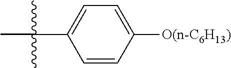 |
| (1-1-52) | 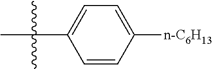 | H | H | 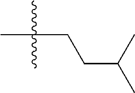 [SMILES: *CCC(C)C] |
| (1-1-53) | 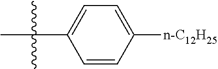 | H | H | 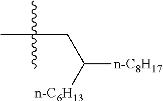 |

TABLE 4

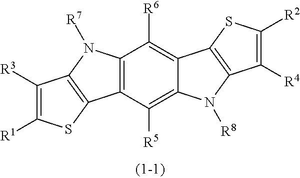

| Compound | | | | |
|---|---|---|---|---|
| number | R¹ and R² | R³ and R⁴ | R⁵ and R⁶ | R⁷ and R⁸ |
| (1-1-54) | O (n-C₄H₉) | H | H | 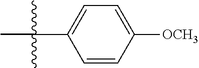 [SMILES: *c1ccc(OC)cc1] |
| (1-1-55) | O (n-C₈H₁₇) | H | H | n-C₄H₉ |
| (1-1-56) | S (n-C₆H₁₃) | H | H | n-C₆H₁₃ |
| (1-1-57) | S (n-C₃H₇) | H | n-C₆H₁₃ | 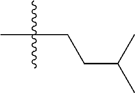 [SMILES: *CCC(C)C] |
| (1-1-58) | 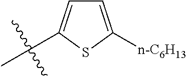 | H | H | n-C₈H₁₇ |
| (1-1-59) | 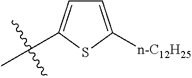 | H | H | 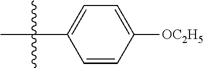 [SMILES: *c1ccc(OCC)cc1] |
| (1-1-60) | 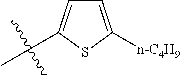 | H | OCH₃ | n-C₆H₁₃ |
| (1-1-61) | 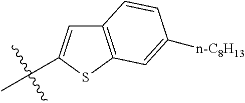 | H | H | n-C₄H₉ |
| (1-1-62) | 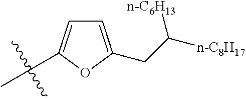 | H | H | n-C₁₂H₂₅ |
| (1-1-63) | CH₃ | CH₃ | H | n-C₆H₁₃ |
| (1-1-64) | S (n-C₆H₁₃) | S (n-C₆H₁₃) | H | 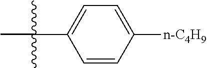 |
| (1-1-65) | Br | H | H | n-C₄H₉ |
| (1-1-66) | Br | H | H | n-C₃H₇ |
| (1-1-67) | Br | H | H | n-C₆H₁₃ |
| (1-1-68) | Br | H | H | 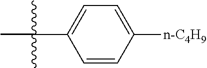 |

TABLE 5

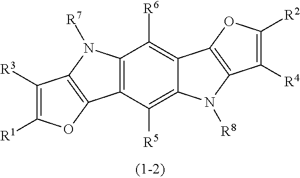

| Compound | | | | |
|---|---|---|---|---|
| number | R¹ and R² | R³ and R⁴ | R⁵ and R⁶ | R⁷ and R⁸ |
| (1-2-1) | H | H | H | H |
| (1-2-2) | H | H | H | n-C₆H₁₃ |
| (1-2-3) | H | H | H | 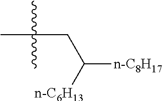 |
| (1-2-4) | H | H | H | n-C₁₂H₂₅ |
| (1-2-5) | H | H | H | 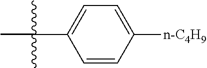 |
| (1-2-6) | 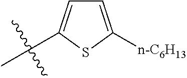 | H | CH₃ | n-C₄H₉ |

TABLE 6

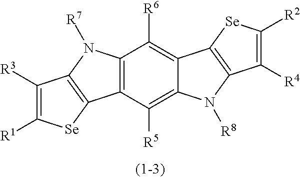

| Compound | | | | |
|---|---|---|---|---|
| number | R¹ and R² | R³ and R⁴ | R⁵ and R⁶ | R⁷ and R⁸ |
| (1-3-1) | H | H | H | H |
| (1-3-2) | H | H | H | n-C₄H₉ |
| (1-3-3) | H | H | H | n-C₁₀H₂₁ |
| (1-3-4) | H | H | C₂H₅ | n-C₆H₁₃ |
| (1-3-5) | H | H | H | 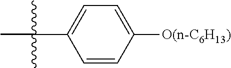 |
| (1-3-6) | 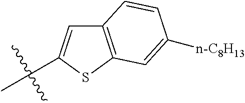 | H | H | 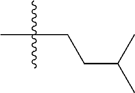 [SMILES: *CCC(C)C] |

TABLE 7

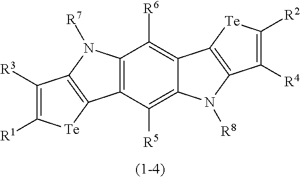

| Compound | | | | |
|---|---|---|---|---|
| number | R¹ and R² | R³ and R⁴ | R⁵ and R⁶ | R⁷ and R⁸ |
| (1-4-1) | H | H | H | H |
| (1-4-2) | H | H | H | n-C₆H₁₃ |
| (1-4-3) | H | H | H | 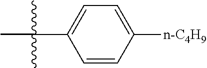 |
| (1-4-4) | 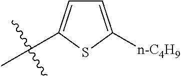 | H | C₂H₅ | 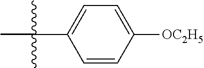 [SMILES: *c1ccc(OCC)cc1] |

TABLE 8

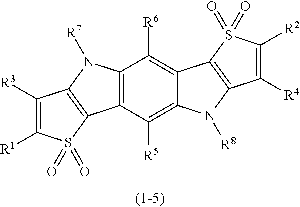

| Compound | | | | |
|---|---|---|---|---|
| number | R¹ and R² | R³ and R⁴ | R⁵ and R⁶ | R⁷ and R⁸ |
| (1-5-1) | H | H | H | H |
| (1-5-2) | H | H | H | C₂H₅ |
| (1-5-3) | H | H | H | s-C₄H₉ |
| (1-5-4) | H | H | H | n-C₆H₁₃ |
| (1-5-5) | H | H | H | 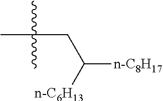 |
| (1-5-6) | H | H | CH₃ | n-C₁₂H₂₅ |
| (1-5-7) | H | H | H | n-C₆H₁₃ |
| (1-5-8) | H | H | H | 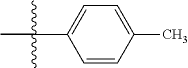 [SMILES: *c1ccc(C)cc1] |
| (1-5-9) | H | H | H | 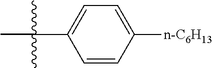 |
| (1-5-10) | H | H | H | 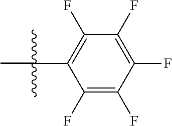 [SMILES: *c1c(F)c(F)c(F)c(F)c1F] |
| (1-5-11) | H | H | H | 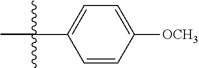 [SMILES: *c1ccc(OC)cc1] |
| (1-5-12) | 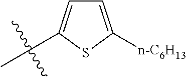 | H | H | n-C₈H₁₇ |

In Tables 1 to 8, the wavy line represents a connecting bond.

Preferable examples of the compound (1) include compound numbers (1-1-1), (1-1-2), (1-1-3), (1-1-4), (1-1-5), (1-1-6), (1-1-8), (1-1-9), (1-1-11), (1-1-12), (1-1-13), (1-1-14), (1-1-15), (1-1-19), (1-1-21), (1-1-22), (1-1-24), (1-1-25), (1-1-26), (1-1-28), (1-1-29), (1-1-30), (1-1-31), (1-1-33), (1-1-35), (1-1-42), (1-1-45), (1-1-51), (1-1-52), (1-1-56), (1-1-58), (1-1-59), (1-1-61), (1-1-64), (1-1-65), (1-1-67), (1-1-68), (1-2-2), (1-2-7), (1-3-3), (1-3-6), (1-4-2), (1-5-4), (1-5-5), (1-5-7), (1-5-9), (1-5-11) and (1-5-12) described in the tables, further preferably (1-1-1), (1-1-2), (1-1-3), (1-1-5), (1-1-6), (1-1-9), (1-1-11), (1-1-12), (1-1-13), (1-1-14), (1-1-21), (1-1-22), (1-1-24), (1-1-25), (1-1-26), (1-1-30), (1-1-31), (1-1-33), (1-1-45), (1-1-58) and (1-1-61).

The compound (1) of the present invention is capable of forming a film by a vacuum process as described later. The compound (1) is capable of forming a film by a solution process, because of excellent dissolvability in an organic solvent. Here, the dissolvable organic solvent includes alcohol solvents such as, for example, water, methanol, ethanol, isopropyl alcohol, butanol and the like, aromatic hydrocarbon solvents such as benzene, toluene, xylene, chlorobenzene, o-dichlorobenzene, trichlorobenzene, fluorobenzene and the like, halogenated aliphatic hydrocarbon solvents such as, for example, dichloromethane, chloroform, 1,2-dichloroethane, 1,1′,2,2′-tetrachloroethane, tetrachloroethylene, carbon tetrachloride and the like, ether solvents such as, for example, diethyl ether, dioxane, tetrahydrofuran, anisole and the like, aliphatic hydrocarbon solvents such as, for example, pentane, hexane, pentane, octane, cyclohexane and the like, ketone solvents such as acetone, methyl ethyl ketone, methyl isobutyl ketone, cyclohexanone and the like, ester solvents such as ethyl acetate, butyl acetate and the like, nitrile solvents such as acetonitrile, propionitrile, methoxyacetonitrile, glutarodinitrile, benzonitrile and the like, and aprotic polar solvents such as dimethyl sulfoxide, sulfolane, N,N-dimethylformamide, N,N-dimethylacetamide, N-methyl-2-pyrrolidone and the like, and of them, preferable are toluene, xylene, o-dichlorobenzene, dichloromethane, chloroform and tetrahydrofuran. Two or more solvents can also be used in admixture.

The concentration of a compound (1) in an organic solution containing the compound (1) is usually in the range of 0.001 to 50% by weight, preferably in the range of 0.01 to 10% by weight, more preferably in the range of 0.1 to 5% by weight.

In the organic solution, not only a compound (1) but also an antioxidant, a stabilizer, an organic semiconductor material, an organic insulating material and the like may be contained in an amount not extremely deteriorating the carrier mobility of a film which is an organic semiconductor layer described later.

The organic semiconductor material may be a low molecular weight material or a high molecular weight material, and may be cross-linked when a cross-linking reaction is possible, or may not be cross-linked. Preferably mentioned are high molecular weight materials. Specific examples thereof include polyacetylene derivatives, polythiophene derivatives, polythienylenevinylene derivatives, polyphenylene derivatives, polyphenylenevinylene derivatives, polypyrrole derivatives, polyaniline derivatives, polytriarylamine derivatives, polyquinoline derivatives, perylene derivatives, tetracene derivatives, pentacene derivatives, phthalocyanine derivatives and the like, and in this case, the content of a compound (1) is preferably 10% by weight or more, more preferably adjusted to 20% by weight or more.

The organic insulating material may be a low molecular weight material or a high molecular weight material, and may be cross-linked when a cross-linking reaction is possible, or may not be cross-linked. Preferably mentioned are high molecular weight materials. Specific examples thereof include polystyrenes, polycarbonates, polydimethylsiloxanes, nylons, polyimides, cyclic olefin copolymers, epoxy polymers, celluloses, polyoxymethylenes, polyolefinic polymers, polyvinyl polymers, polyester polymers, polyether polymers, polyamide polymers, fluorine-based polymers, biodegradable plastics, phenol resins, amino resins, unsaturated polyester resins, dially phthalate resins, epoxy resins, polyimide resins, polyurethane resins, silicone resins, and copolymers combining various polymer units, and the like, and in this case, the content of a compound (1) is preferably 10% by weight or more, more preferably adjusted to 20% by weight or more.

In a method of preparing an organic solution, the organic solution can be obtained by dissolving a compound (1) in an organic solvent at a temperature, for example, in the range of 10 to 200° C. and the like, preferably in the range of 20 to 150° C. and the like.

The compound (1) of the present invention can be produced, for example, by reacting a compound represented by the formula (2):

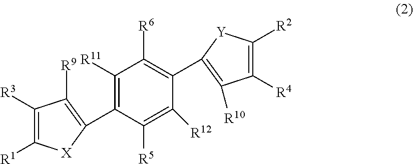

(wherein, R¹ to R⁶, X and Y are as defined above, and R⁹ to R¹² represent each independently a halogen atom, preferably bromine or iodine.)
(compound (2))
and amine compounds represented by the formulae:

R⁷—NH₂ and R⁸—NH₂

(wherein, R⁷ and R⁸ represent a hydrogen atom, a halogen atom, an alkyl group having 1 to 30 carbon atoms optionally substituted by a fluorine atom, an alkoxy group having 1 to 30 carbon atoms optionally substituted by a fluorine atom, an alkenyl group having 2 to 30 carbon atoms optionally substituted by a fluorine atom, an alkynyl group having 2 to 30 carbon atoms optionally substituted by a fluorine atom, an alkylthio group having 1 to 30 carbon atoms optionally substituted by a fluorine atom, an aryl group having 6 to 30 carbon atoms or a heteroaryl group having 4 to 30 carbon atoms. The aryl group and the heteroaryl group may have a fluorine atom, an alkyl group optionally substituted by a fluorine atom, an alkoxy group optionally substituted by a fluorine atom, an alkenyl group optionally substituted by a fluorine atom, an alkynyl group optionally substituted by a fluorine atom or an alkylthio group optionally substituted by a fluorine atom.).

When only an amine compound represented by the formula (3):

R⁷—NH₂ (3)

(wherein, R⁷ represents a hydrogen atom, a halogen atom, an alkyl group having 1 to 30 carbon atoms optionally substituted by a fluorine atom, an alkoxy group having 1 to 30 carbon atoms optionally substituted by a fluorine atom, an alkenyl group having 2 to 30 carbon atoms optionally substituted by a fluorine atom, an alkynyl group having 2 to 30 carbon atoms optionally substituted by a fluorine atom, an alkylthio group having 1 to 30 carbon atoms optionally substituted by a fluorine atom, an aryl group having 6 to 30 carbon atoms or a heteroaryl group having 4 to 30 carbon atoms. The aryl group and the heteroaryl group may have a fluorine atom, an alkyl group optionally substituted by a fluorine atom, an alkoxy group optionally substituted by a fluorine atom, an alkenyl group optionally substituted by a fluorine atom, an alkynyl group optionally substituted by a fluorine atom or an alkylthio group optionally substituted by a fluorine atom.)
is used as the amine compound, a dichalcogenobenzodipyrrole compound represented by the above-described formula (1′) is produced.

The compound (2) used in production of a compound (1) includes, for example, compounds shown in the following tables.

TABLE 9

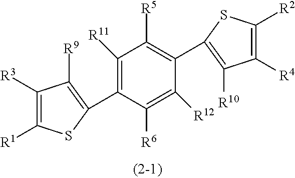

| Compound | | | | R⁹, R¹⁰, R¹¹ |
|---|---|---|---|---|
| number | R¹ and R² | R³ and R⁴ | R⁵ and R⁶ | and R¹² |
| (2-1-1) | H | H | H | Br |
| (2-1-2) | H | H | H | I |
| (2-1-3) | H | H | CH₃ | Br |
| (2-1-4) | H | H | C₂H₅ | Br |
| (2-1-5) | H | H | n-C₆H₁₃ | Br |
| (2-1-6) | H | H | n-C₁₂H₂₅ | I |
| (2-1-7) | H | H | 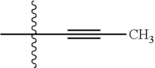 [SMILES: *C#CC] | Br |
| (2-1-8) | H | H | 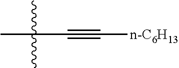 | Br |
| (2-1-9) | H | H | OCH₃ | Br |
| (2-1-10) | H | H | S (n-C₆H₁₃) | Br |
| (2-1-11) | H | H | 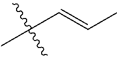 [SMILES: */C=C/C] | Br |
| (2-1-12) | CH₃ | H | H | Br |
| (2-1-13) | n-C₄H₉ | H | H | Br |
| (2-1-14) | 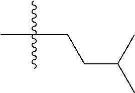 [SMILES: *CCC(C)C] | H | CH₃ | I |
| (2-1-15) | n-C₆H₁₃ | H | H | Br |
| (2-1-16) | n-C₈H₁₇ | H | H | Br |
| (2-1-17) | 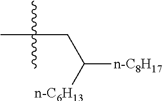 | H | H | Br |
| (2-1-18) | n-C₁₂H₂₅ | H | H | Br |
| (2-1-19) | n-C₂₉H₄₁ | H | 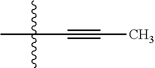 [SMILES: *C#CC] | Br |
| (2-1-20) | 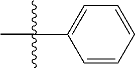 [SMILES: *c1ccccc1] | H | H | Br |
| (2-1-21) | 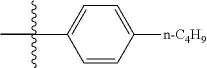 | H | H | Br |
| (2-1-22) | 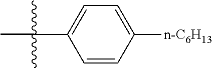 | H | H | Br |
| (2-1-23) | 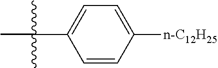 | H | H | Br |

TABLE 10

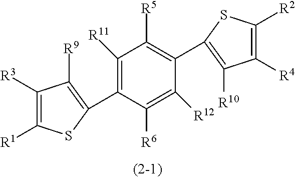

| Compound | | | | R⁹, R¹⁰, |
|---|---|---|---|---|
| number | R¹ and R² | R³ and R⁴ | R⁵ and R⁶ | R¹¹ and R¹² |
| (2-1-24) | O (n-C₄H₉) | H | H | Br |
| (2-1-25) | O (n-C₉H₁₇) | H | H | Br |
| (2-1-26) | S (n-C₆H₁₃) | H | H | Br |
| (2-1-2 7) | S (n-C₃H₇) | H | n-C₆H₁₃ | Br |
| (2-1-28) | 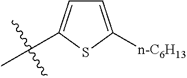 | H | H | Br |
| (2-1-29) | 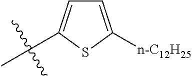 | H | H | Br |
| (2-1-30) | 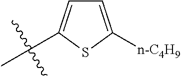 | H | OCH₃ | Br |
| (2-1-31) | 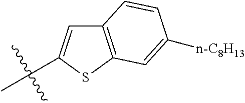 | H | H | Br |
| (2-1-32) | 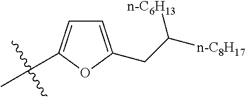 | H | H | I |
| (2-1-33) | CH₃ | CH₃ | H | Br |
| (2-1-34) | S (n-C₆H₁₃) | S (n-C₆H₁₃) | H | I |
| (2-1-35) | Br | H | H | Br |

TABLE 11

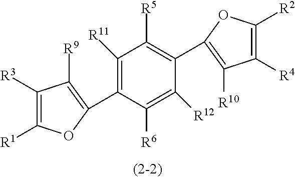

| | | R³ | R⁵ | R⁹, R¹⁰, |
|---|---|---|---|---|
| Compound | | and | and | R¹¹ |
| number | R¹ and R² | R⁴ | R⁶ | and R¹² |
| (2-2-1) | H | H | H | Br |
| (2-2-2) | 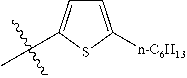 | H | CH₃ | Br |

TABLE 12

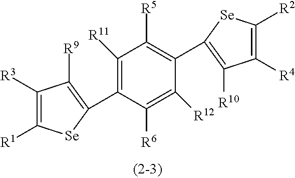

| Compound | | R³ and | R⁵ and | R⁹, R¹⁰, R¹¹ |
|---|---|---|---|---|
| number | R¹ and R² | R⁴ | R⁶ | and R¹² |
| (2-3-1) | H | H | H | Br |
| (2-3-2) | 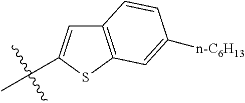 | H | H | Br |

TABLE 13

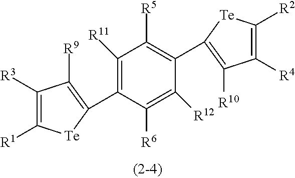

| | | R³ | R⁵ | R⁹, R¹⁰, |
|---|---|---|---|---|
| Compound | | and | and | R¹¹ |
| number | R¹ and R² | R⁴ | R⁶ | and R¹² |
| (2-4-1) | H | H | H | Br |
| (2-4-2) | 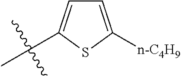 | H | H | Br |

TABLE 14

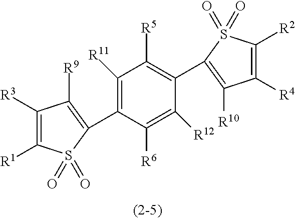

| Compound | | R³ and | R⁵ and | R⁹, R¹⁰, R¹¹ |
|---|---|---|---|---|
| number | R¹ and R² | R⁴ | R⁶ | and R¹² |
| (2-5-1) | H | H | H | Br |
| (2-5-2) | H | H | CH₃ | Br |
| (2-5-3) | H | H | H | I |
| (2-5-4) | 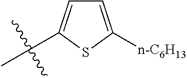 | H | H | Br |

In Tables 9 to 14, the wavy line represents a connecting bond.

The amine compound used in the reaction includes, for example, linear alkylamines such as methylamine, ethylamine, n-propylamine, isopropylamine, n-butylamine, n-pentylamine, n-hexylamine, n-heptylamine, n-octylamine, n-nonylamine, n-decylamine, n-undecylamine, n-dodecylamine, n-tridecylamine, n-tetradecylamine, n-pentadecylamine, n-hexadecylamine, n-heptadecylamine, n-octadecylamine, n-nonadecylamine, n-icosylamine, n-henicosylamine, n-docosylamine, n-tricosylamine, n-tetracosylamine, n-pentacosylamine, n-hexacosylamine, n-heptacosylamine, n-octacosylamine, n-nonacosylamine, n-triacontylamine and the like; aniline, and anilines having an alkyl group such as 4-methylaniline, 4-ethylaniline, 4-n-propylaniline, 4-isopropylaniline, 4-n-butylaniline, 4-n-pentylaniline, 4-n-hexylaniline, 4-n-heptylaniline, 4-n-octylaniline, 4-n-nonylaniline, 4-n-decylaniline, 4-n-undecylaniline, 4-n-dodecylaniline, 4-n-tridecylaniline, 4-n-tetradecylaniline and the like.

The use amount of the amine compound used in the reaction is usually 1 to 50 mol, preferably 2 to 20 mol, more preferably 2 to 15 mol with respect to 1 mol of a compound (2).

It is preferable that the reaction is carried out in an organic solvent.

The above-described organic solvent may advantageously be an organic solvent inert to the above-described reaction, and includes, for example, aromatic hydrocarbon solvents such as toluene, xylene and the like; halogenated aromatic hydrocarbon solvents such as chlorobenzene, o-dichlorobenzene and the like; aliphatic hydrocarbon solvents such as hexane, heptane, dimethoxyethane and the like; halogenated aliphatic hydrocarbon solvents such as chloroform, 1,2-dichloroethane and the like; alcohols having 1 to 4 carbon atoms such as methanol, isopropyl alcohol, t-butyl alcohol and the like; ether solvents such as tetrahydrofuran, dioxane and the like; and mixed solvents thereof, preferably aromatic hydrocarbon solvents and aliphatic hydrocarbon solvents, more preferably toluene and xylene.

The concentration of a compound (2) in the reaction liquid is, for example, 0.0001 to 20 mol, preferably 0.001 to 10 mol, more preferably 0.01 to 5 mol with respect to 1 liter of an organic solvent.

It is preferable that the reaction is carried out in the presence of a palladium catalyst and a base.

The use amount of the palladium catalyst is usually 0.01 to 50 mol, preferably 0.01 to 30 mol reduced by a palladium atom with respect to 100 mol of a compound (2).

As the palladium catalyst, those prepared by previously allowing a compound acting as a ligand and a palladium compound to contact with each other in an organic solvent may be used, or those prepared by allowing a compound acting as a ligand and a palladium compound to contact with each other in the reaction system may be used

As the above-described compound acting as a ligand, those coordinatable to palladium and soluble in an organic solvent may be permissible, and examples thereof include monodentate phosphine ligands, polydentate ligands, carbene ligands and the like, and preferable are monodentate ligands, more preferable are monodentate phosphine ligands.

The monodentate phosphine ligand includes, for example, tri(n-butyl)phosphine, tri(t-butyl)phosphine, tricyclohexylphosphine, triphenylphosphine, tri(o-tolyl)phosphine, trinaphthylphosphine, diphenylnaphthylphosphine and dicyclohexylnaphthylphosphine, and preferable is tri(t-butyl)phosphine.

The bidentate ligand includes, for example, bidentate phosphine ligands having two phosphorus atoms such as 2,2′-bis(diphenylphosphino)-1,1′-binaphthyl, 1,2-bis(diphenylphosphino)ethane, 1,3-bis(diphenylphosphino)propane, 1,4-bis(diphenylphosphino)butane, 1,1′-(diphenylphosphino)ferrocene, 4,5-bis(diphenylphosphino)-9,9-dimethylxanthene, 2,2′-bis(diphenylphosphino)diphenyl ether, 5,5′-bis(diphenylphosphino)-4,4′-bi(1,3-benzodioxole) and the like; and bidentate aminophosphine ligands having one nitrogen atom and one phosphorus atom such as 2-(N,N-dimethylamino)-2′-(dicyclohexylamino)biphenyl and the like.

As the ligand, commercially available products may be used as they are, or those produced by known methods may be used.

The use amount of the ligand is advantageously 0.5 to 20 mol with respect to 1 mol of a palladium atom of a palladium compound.

The above-described palladium compound includes divalent palladium compounds such as palladium acetate, palladium chloride, dichlorobis(acetonitrile)palladium, palladiumacetylacetonate, dichloro(cycloocta-1,5-diene)palladium, dibromobis(benzonitrile)palladium, di-μ-chlorobis(n-allyl)dipalladium, dichlorobis(pyridine)palladium, dichlorobis(triphenylphosphine)palladium, dichloro-[1,1′-bis(diphenylphosphino)ferrocene]palladium •dichloromethane complex and the like; 0-valent palladium compounds such as tris(dibenzylideneacetone)dipalladium, tris(dibenzylideneacetone)dipalladium•chloroform complex, tetrakis(triphenylphosphine)palladium and the like; etc., and of them, tris(dibenzylideneacetone)dipalladium and tris(dibenzylideneacetone)dipalladium•chloroform complex are preferable. As the palladium compound, commercially available products may be used as they are, or those produced by known methods may be used.

The base includes, for example, alkaline earth metal hydroxides such as calcium hydroxide and the like; alkali metal carbonates such as potassium carbonate, sodium carbonate, cesium carbonate and the like; alkaline earth metal carbonates such as magnesium carbonate, calcium carbonate, barium carbonate and the like; alkali metal phosphates such as lithium phosphate, potassium phosphate, sodium phosphate and the like; and alkali metal alkoxides such as sodium methoxide, sodium ethoxide, sodium t-butoxide, potassium methoxide, potassium ethoxide, potassium t-butoxide, lithium t-butoxide and the like, preferably alkali metal carbonates and alkali metal alkoxides, more preferably alkali metal alkoxides, further preferably alkali metal alkoxides having 1 to 6 carbon atoms. The base may be used singly, or two or more bases may be used in admixture.

The use amount of the base is, for example, 0.1 to 25 mol, preferably to 20 mol, further preferably 2 to 10 mol with respect to 1 mol of a compound (2). When the use amount of the base is 25 mol or less, there is a preferable tendency of lowering of the proportion of an unreacted amine compound (3).

The reaction temperature is selected in the range of from 0° C. to the reflux temperature of the reaction liquid, and preferably in the range of 40 to 200° C. The reaction time is usually in the range of from 1 minute to 120 hours.

In stopping the reaction, for example, water, dilute hydrochloric acid and the like are added to the reaction liquid. After stopping of the reaction, a post treatment operation such as, for example, extraction, washing and the like can be carried out to obtain a coarse product of a compound (1). The coarse product can be purified by a purification operation such as crystallization, sublimation, various chromatographies and the like, or purification operations combining them.

A compound (2) can be produced by subjecting a compound represented by the general formula (4):

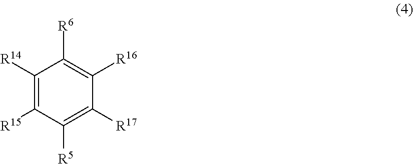

(wherein, R⁵ and R⁶ are as defined above. R¹⁴ to R¹⁷ represent each independently a halogen atom.)
(compound (4))
and a compound represented by the general formula (5):

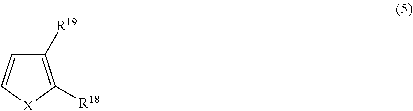

(wherein, X is as defined above. R¹⁸ and R¹⁹ represent each independently a halogen atom.)
(compound (5))
to the Negishi Coupling reaction in the presence of a transition metal catalyst according to a method described, for example, in US2011/168953.

The film of the present invention is a film containing a compound (1), and is a film having a thickness of, for example, 1 nm to 10 μm, preferably 5 nm to 1 μm.

The film of the present invention sometimes shows a luminescent property and similar electric conductivity to that of a semiconductor, and is excellent also as a luminescent film and an electric conductive film, respectively.

In the present invention, the luminescent film is a film containing a compound (1), and means a film emitting light under conditions of light and electric stimuli. The luminescent film is useful as a material of a light emitting device. Also a light emitting device having a luminescent film is one of the present invention. The light emitting device of the present invention is useful, for example, as a material of an organic light emitting diode and the like.

In the present invention, the light emitting device means a device using the luminescent film.

In the present invention, the electric conductive film means a film showing electric conductivity under conditions of light and electric stimuli. The electric conductive film showing similar electric conductivity to that of a semiconductor is referred to particularly as an organic semiconductor film in some cases. The electric conductive film is useful as a material of an organic semiconductor device and the like described later.

The electric conductive film and luminescent film of the present invention can be produced in a like manner as in conventionally known methods excepting that the compound (1) of the present invention is used as a material.

Next, the organic transistor will be illustrated.

The organic transistor of the present invention contains the film of the present invention.

The above-described organic transistor has high carrier mobility since it contains the compound (1) of the present invention. The above-described organic transistor can have a carrier mobility of 10⁻⁶ cm²/Vs or more. Here, carrier mobility can be measured by applying the following formula (a) to drain current and gate voltage measured using a parameter analyzer and the like.

Id=(W/2L)μCi(Vg−Vt)₂ (a)

(wherein, Id=drain current in saturation region of electric property, L=channel length of organic transistor, W=channel width of organic transistor, Ci=capacity per unit area of gate insulation film, Vg=gate voltage, Vt=threshold voltage of gate voltage)

The organic transistor of the present invention includes organic electric field effect transistors.

The organic electric field effect transistor may be usually a device in which a source electrode and a drain electrode are in contact with a semiconductor layer, and further, a gate electrode is disposed so as to sandwich an insulation layer (dielectric layer) in contact with an active layer.

The device structure of the above-described organic transistor includes, for example,

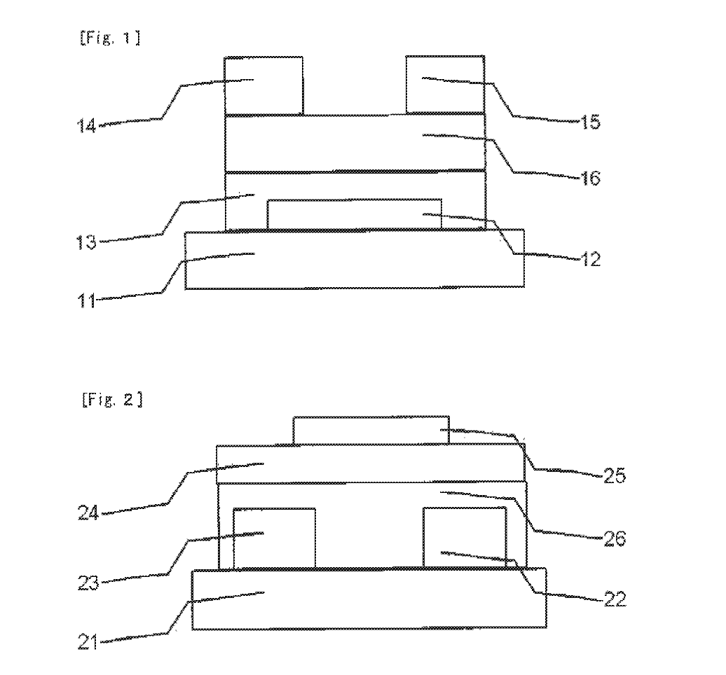

(1) a structure composed of substrate/gate electrode/insulator layer/source electrode-drain electrode/semiconductor layer;
(2) a structure composed of substrate/gate electrode/insulator layer/semiconductor layer/source electrode-drain electrode (see, FIG. 1);
(3) a structure composed of substrate/semiconductor layer+source electrode•drain electrode/insulator layer/gate electrode (see, FIG. 2);
(4) a structure composed of substrate/source electrode (or drain electrode)/semiconductor layer+insulator layer+gate electrode/drain electrode (or source electrode).

In the above-described each structure, the semiconductor layer has the organic semiconductor film of the present invention. When two or more semiconductor layers are present in each structure, these may be disposed on the same plane, or may be laminated. In the above-described each structure, two or more source electrodes, two or more drain electrodes and two or more gate electrodes may be provided, respectively.

The method of forming an organic semiconductor layer containing a compound (1) as a film in an organic transistor includes, for example, vacuum process formation methods such as a vacuum vapor deposition method, a sputtering method, a CVD method, a molecular beam epitaxial growth method and the like, preferably a vacuum vapor deposition method.

The vacuum vapor deposition method is a method in which an organic semiconductor material such as a compound (1) and the like is heated in a crucible or a metal boat in vacuo, and the evaporated organic semiconductor material is vapor-deposited on a substrate or an insulator material.

The degree of vacuum in vapor deposition is 1×10⁻¹ Pa or less, preferably 1×10⁻³ Pa or less.

The substrate temperature in vapor deposition is 0° C. to 300° C., preferably 20° C. to 200° C.

The vapor deposition speed is 0.001 nm/sec to 10 nm/sec, preferably 0.01 nm/sec to 1 nm/sec. The thickness of the above-described organic semiconductor film is 1 nm to 10 μm, preferably 5 nm to 1 μm.

As another embodiment of the method of forming an organic semiconductor layer containing a compound (1) as a film in an organic transistor, coating film formation processing can be exemplified since the compound (1) is excellent in dissolvability in an organic solvent. Coating film formation processing usually has a step of preparing a composition in the form of a solution obtained by dissolving a compound (1) in an organic solvent and coating the composition on a substrate or an insulator layer, and a step of drying a coated film coated on the substrate. The step of coating includes, for example, coating methods such as a casting method, a dip coat method, a die coater method, a roll coater method, a bar coater method, a spin coat method and the like, an inkjet method, a screen printing method, an offset printing method, a micro contact printing method and the like. These steps may be used singly or may be used in combination.

The coated film obtained by the step of coating can be dried, namely, an organic solvent contained in the composition can be removed, to obtain the film of the present invention. The drying method includes, for example, a natural drying treatment, a heating treatment, a pressure reducing treatment, a ventilating treatment, treatments combining them, and the like, and preferable is a natural drying treatment or a heating treatment owing to a simple operation. Specifically mentioned are leaving under atmospheric air, a treatment of heating a substrate on a hot plate (for example, 40 to 250° C., preferably 50 to 200° C.) and the like.

In the composition, a compound (1) may also be dispersed in an organic solvent even if the compound is not dissolved in the organic solvent. It means that the above-described composition is a dispersion prepared by dispersing a compound (1) in a solvent in a specific embodiment of this case.

As the method of forming an organic semiconductor layer as a film in an organic transistor, coating film formation processing is preferable using a composition obtained by dissolving a compound (1) in an organic solvent. An organic transistor obtained from such a film shows excellent carrier mobility.

In the organic transistor of the present invention, materials constituting a source electrode, a drain electrode and a gate electrode are not particularly limited providing they are general electric conductive materials, and use is made of platinum, gold, silver, nickel, chromium, copper, iron, tin, lead antimony, tantalum, indium, palladium, tellurium, rhenium, iridium, aluminum, ruthenium, germanium, molybdenum, tungsten, tin*antimony oxide, indium*tin oxide (ITO), fluorine-doped zinc oxide, zinc, carbon, graphite, glassy carbon, silver paste and carbon paste, lithium, beryllium, sodium, magnesium, potassium, calcium, scandium, titanium, manganese, zirconium, gallium, niobium, sodium, a sodium-potassium alloy, magnesium, lithium, aluminum, a magnesium/copper mixture, a magnesium/silver mixture, a magnesium/aluminum mixture, a magnesium/indium mixture, an aluminum/aluminum oxide mixture, a lithium/aluminum mixture, molybdenum oxide and the like, and particularly preferable are platinum, gold, silver, copper, aluminum, nickel, indium, ITO, carbon and molybdenum oxide. Also known electric conductive polymers having electric conductivity improved by doping and the like, for example, electric conductive polyaniline, electric conductive polypyrrole, electric conductive polythiophene, a complex of polyethylenedioxythiophene and polystyrene sulfonic acid, and the like are suitably used. Of them, those showing low electric resistance at a surface in contact with a semiconductor layer are preferable. These electrode materials may be used singly or two or more of them may be used in combination.

The thickness of an electrode varies depending on the material, and may be advantageously 0.1 nm to 10 μm, preferably 0.5 nm to 5 μm, more preferably 1 nm to 3 μm. When acting as a gate electrode and a substrate simultaneously, values larger than the above-described thickness may be permissible.

The method of forming an electrode film includes various known methods. Specifically mentioned are a vacuum vapor deposition method, a sputtering method, a coating method, a thermal transfer method, a printing method, a sol-gel method and the like. It is preferable that patterning is carried out, if necessary, in film formation or after film formation. Also as the patterning method, various methods can be used. Specifically, there are a photo-lithography method combining etching and patterning of a photo-resist, and the like. Further mentioned are printing methods such as inkjet printing, screen printing, offset printing, relief printing and the like, methods of soft lithography such as a micro contact printing method and the like. These methods may be used singly, or two or more of them can be combined for performing patterning.

As the insulation layer, use can be made of various insulation films such as films of inorganic oxides and organic compounds, and the like. The inorganic oxide includes silicon oxide, aluminum oxide, tantalum oxide, titanium oxide, tin oxide, vanadium oxide, barium strontium titanate, barium zirconate titanate, lead zirconate titanate, lead lanthanum titanate, strontium titanate, barium titanate, barium magnesium fluoride, bismuth titanate, strontium bismuth titanate, strontium bismuth tantalate, bismuth tantalate niobate, trioxide yttrium and the like, and preferable are silicon oxide, aluminum oxide, tantalum oxide and titanium oxide. Inorganic nitrides are listed such as silicon nitride, aluminum nitride and the like. The organic compound includes polystyrenes, polyimides, polyamides, polyesters, polyacrylates, photo-radical polymerizing and photo-cation polymerizing photo-curable resins, copolymers containing an acrylonitrile component, polyvinyl phenols, polyvinyl alcohols, novolak resins, cyanoethylpullulan and the like, preferably polystyrenes, polyimides, polyvinyl phenols and polyvinyl alcohols.

These insulation layer materials may be used singly or two or more of them may be used in combination. The thickness of the insulation layer varies depending on the material, and is usually 0.1 nm to 100 μm, preferably 0.5 nm to 50 μm, more preferably 5 nm to 10 μm.

As the method of forming the insulation layer, various known methods can be used. Specifically mentioned are coating methods such as spin coating, spray coating, dip coating, cast, bar coat, blade coating and the like, printing methods such as screen printing, offset printing, inkjet and the like, and dry process methods such as a vacuum vapor deposition method, a molecular beam epitaxial growth method, an ion cluster beam method, an ion plating method, a sputtering method, an atmospheric pressure plasma method, a CVD method and the like. Additionally mentioned are a sol-gel method, a method of forming an oxide film on a metal such as alumite and a thermally-oxidized film of silicon on aluminum, and the like.

The substrate includes a plate or a sheet constituted of a substrate material such as glass, paper, quartz, ceramic or flexible resins, and the like. The material of the resin film includes, specifically, polyethylene terephthalate (PET), polyethylene naphthalate (PEN), polyether sulfone (PES), polyetherimide, polyether ether ketone, polyphenylene sulfide, polyarylate, polyimide, polycarbonate (PC), cellulose triacetate (TAC), cellulose acetate propionate (CAP) and the like. The thickness of the substrate is preferably 1 μm to 10 mm, further preferably 5 μm to 5 mm.

A surface treatment may be performed on an insulator layer and a substrate at parts thereof in contact with an organic semiconductor layer. By performing a surface treatment on an insulator layer on which a semiconductor layer is laminated, the transistor property of a device can be improved. The surface treatment includes, specifically, hydrophobization treatments with hexamethyldisilazane, octadecyltrichlorosilane, octyltrichlorosilane, phenethyltrichlorosilane and the like, acid treatments with hydrochloric acid, sulfuric acid, hydrogen peroxide water and the like, treatments with sodium hydroxide, potassium hydroxide, calcium hydroxide, ammonia and the like, an ozone treatment, a fluorinating treatment, plasma treatments with oxygen, argon and the like, a treatment of forming a Langmuir-Blodgett film, a treatment of forming a film of other insulators, semiconductors and the like, a mechanical treatment, an electric treatment such as corona discharge and the like, a rubbing treatment utilizing fibers, and the like, and two or more treatment methods may be used in combination.

The method of performing a surface treatment includes, for example, a vacuum vapor deposition method, a sputtering method, a coating method, a printing method, a sol-gel method and the like.

A protective film composed of a resin or an inorganic compound may be provided on a semiconductor layer. By formation of the protective layer, an influence by an ambient air can be suppressed and thus driving of a transistor can be stabilized.

The organic transistor of the present invention can be used in organic semiconductor devices such as, for example, liquid crystal displays, organic electric field light emitting devices, electronic paper, sensors, RFIDs (radio frequency identification cards) and the like.

### EXAMPLES

The present invention will be illustrated further in detail by examples below.

For confirmation of progress of the reaction, high performance liquid chromatograph (LC) was used.

### 1. High Performance Liquid Chromatographic Analysis

Apparatus: Shimadzu LC10AT

Column: manufactured by Chemicals Evaluation and Research Institute, Japan, L-column ODS, internal diameter: 4.6 mm, length: 15 cm

For recycling preparative high performance liquid chromatographic purification, the following apparatus and column were used.

Apparatus: LC-250HS (manufactured by Japan Analytical Industry Co., Ltd.)

Column: manufactured by Japan Analytical Industry Co., Ltd., JAIGEL-ODS-AP-50L, internal diameter: 50 mm, length: 25 cm

In each example, identification of a product was determined by measurement using the following apparatuses.

1. ¹H-NMR: EX270 (manufactured by JEOL)
2. LC-HRMS: apparatus: QSTAR XL (manufactured by Applied Biosystems), column: manufactured by Chemicals Evaluation and Research Institute, Japan, L-column ODS, internal diameter: 4.6 mm, length: 15 cm

### Production Example 1

### Production of 1,4-bis(3-bromothiophen-2-yl)-2,5-dibromobenzene (compound number (2-1-1))

1,4-bis(3-bromothiophen-2-yl)-2,5-dibromobenzene was prepared as described below in reference to US2011/168953. A raw material 1,4-dibromo-2,5-diiodobenzene was prepared by reacting 1,4-dibromobenzene and iodine (see, J. Org. Chem., 1985, p. 3104).

Into a 1000 mL four-necked flask equipped with a stirring bar, a thermometer, a condenser and a dropping funnel was charged 2,3-dibromothiophene (manufactured by Tokyo Chemical Industry Co., Ltd., 22.3 g, 92.3 mmol), the atmosphere in the system was purged with nitrogen, and 240 ml of dehydrated tetrahydrofuran was added through a syringe at room temperature (about 25° C.). The solution was cooled down to −78° C., and a tetrahydrofuran solution (92.3 ml, 92.3 mmol) containing isopropyl magnesium bromide (manufactured by Tokyo Chemical Industry Co., Ltd., 1.00 M) was added at the same temperature from a dropping funnel over a period of 1 hour, and the mixture was stirred at the same temperature for 30 minutes. To the solution was added a diethyl ether solution (92.3 ml, 92.3 mmol) containing zinc chloride (manufactured by Aldrich, 1.00 M) at −78° C. from a dropping funnel over a period of 1 hour, and the mixture was stirred at the same temperature for 10 minutes. The temperature of the solution was raised gradually to room temperature, then, the solvent was distilled off under reduced pressure to obtain a white crystal. Into the flask containing this crystal were charged 1,4-dibromo-2,5-diiodobenzene (15.0 g, 30.8 mmol) and tetrakistriphenylphosphine (manufactured by Tokyo Chemical Industry Co., Ltd., 3.5 g, 3.1 mmol), the atmosphere in the system was purged with nitrogen, 240 ml of dehydrated tetrahydrofuran was added through a syringe, and the mixture was stirred under reflux for 7 hours. The solution was cooled down to room temperature, and the solvent was removed under reduced pressure. To the concentrated residue were added a 10% ammonium chloride aqueous solution (weight ratio) and toluene and the solution was allowed to separate, and the resultant toluene layer was dried over magnesium sulfate, filtrated, then, the solvent was distilled off under reduced pressure. To the resultant mixture was added hexane and the mixture was refluxed for 10 minutes, then, cooled down to room temperature, the mixture was filtrated, and the material on the filter was dried under reduced pressure. To the dried material on the filter was added chloroform and the mixture was refluxed for 10 minutes, then, cooled down to room temperature, the mixture was filtrated, and the material on the filter was dried under reduced pressure, to obtain a white crystal of 1,4-bis(3-bromothiophen-2-yl)-2,5-dibromobenzene (12.3 g, 22.0 mmol) at a yield of 71% with respect to 1,4-dibromo-2,5-diiodobenzene. Its structural formula is shown below.

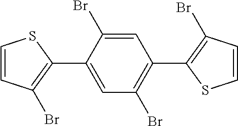 [SMILES: Brc1cc(-c2sccc2Br)c(Br)cc1-c1sccc1Br]

The physical property of 1,4-bis(3-bromothiophen-2-yl)-2,5-dibromobenzene was as described below.

¹H-NMR (δ, CDCl₃): 7.09 (d, 2H), 7.42 (d, 2H), 7.71 (s, 2H)

### Example 1

### Production Example of Compound (1-1-26)

Into a 500 mL four-necked flask equipped with a stirring bar, a thermometer and a condenser were charged a compound (2-2-1) (10.00 g, 17.92 mmol), tris(dibenzylideneacetone)dipalladium (3.28 g, 3.69 mmol), tri-tert-butylphosphine (1.45 g, 7.17 mmol), p-dodecylaniline (18.74 g, 71.69 mmol), sodium tert-butoxide (10.33 g, 107.54 mmol) and dehydrated toluene (300 ml) under a nitrogen atmosphere, and the mixture was heated up to 80° C. under a nitrogen atmosphere and stirred at the same temperature for 24 hours. The resultant reaction mass was cooled down to room temperature, then, water and toluene were added and the solution was allowed to separate, and the resultant organic layer was dried over magnesium sulfate, filtrated, then, the solvent was distilled off under reduced pressure, to obtain a solid. This solid was re-crystallized from toluene twice, then, the resultant crystal was dissolved in tetrahydrofuran, and activated carbon was added to the dissolved solution, and the mixture was stirred at room temperature for 30 minutes, then, filtrated. From the resultant filtrate, the solvent was distilled off under reduced pressure, and the resultant crystal was re-crystallized from toluene, to obtain a whitish yellow crystal of a compound (1-1-26) (4.29 g, 5.67 mmol) at a yield of 32%.

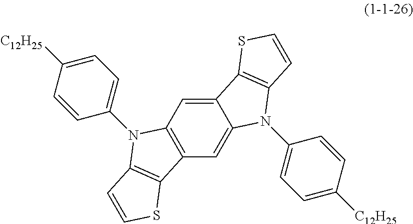

The physical properties of the compound (1-1-26) were as described below.

¹H-NMR (δ, tetrahydrofuran-d₈): 0.90 (t, 6H), 1.23 to 1.53 (m, 40H), 2.75 (t, 4H), 7.11 (d, 2H), 7.42 (d, 2H), 7.45 (d, 4H), 7.62 (d, 4H), 7.69 (s, 2H)

LC-HRMS (APPI+): calcd for C₅₀H₆₅N₂S₂, 757.4583. found 757.457

### Example 2

### Production Example of Compound (1-1-14)

Into a 300 mL four-necked flask equipped with a stirring bar, a thermometer and a condenser were charged a compound (2-2-1) (5.00 g, 8.96 mmol), tris(dibenzylideneacetone)dipalladium (1.64 g, 1.79 mmol), racemic-2,2′-bis(diphenylphosphino)-1,1′-binaphthyl (2.23 g, 3.59 mmol), dodecylamine (6.64 g, 35.85 mmol), sodium tert-butoxide (5.17 g, 53.77 mmol) and dehydrated toluene (150 ml) under a nitrogen atmosphere, and the temperature thereof was raised under a nitrogen atmosphere until reflux and the mixture was stirred at the same temperature for 8 hours. The resultant reaction mass was cooled down to room temperature, then, water and toluene were added and the solution was allowed separate, and the resultant organic layer was dried over magnesium sulfate, filtrated, then, the solvent was distilled off under reduced pressure, to obtain a solid. The resultant solid was separated and purified by silica gel chromatography using a hexane-toluene mixed solvent containing triethylamine added at a volume ratio of 0.2%, and the resultant mixture was re-crystallized from a hexane-toluene mixed solvent. The resultant crystal was further purified by recycling preparative high performance liquid chromatography (moving bed; tetrahydrofuran-acetonitrile mixed solvent), to obtain a whitish yellow crystal of a compound (1-1-14) (0.67 g, 1.11 mmol) at a yield of 12%.

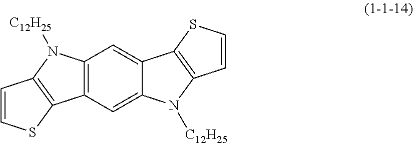

The physical properties of the compound (1-1-14) were as described below.

¹H-NMR (δ, tetrahydrofuran-d₈): 0.88 (t, 6H), 1.20 to 1.45 (m, 36H), 1.84 to 1.98 (m, 4H), 4.38 (t, 4H), 7.15 (d, 2H), 7.38 (d, 2H), 7.71 (s, 2H)

LC-HRMS (APPI+): calcd for C₃₈H₅₇N₂S₂, 605.3957. found 605.3944

### Example 3

### Production Example of Organic Semiconductor Transistor Having Electric Conductive Film of Compound (1) As Organic Semiconductor Layer

On a glass substrate, chromium and gold were vapor-deposited in this order using lift-off process or photolithography, to provide a source electrode and a drain electrode. Under this condition, the thickness of the chromium layer was 5 nm and the thickness of the gold layer was 40 nm. After providing the electrodes, the substrate was subjected to ultrasonic cleaning using acetone and isopropyl alcohol in this order, dried, then, cleaned with oxygen plasma, then, heated at 80° C. for 5 minutes for a dehydration operation. Under this condition, the channel width was 2 mm and the channel length was 100 μm. The channel part was treated with phenethyltrichlorosilane and the electrode part was treated with pentafluorobenzenethiol, then, under a nitrogen atmosphere, a 0.4 wt % o-xylene solution of the compound (1-1-26) produced in Example 1 was dropped and spin-coated to form an organic layer, next, on the organic layer, a solution containing a fluorine-based polymer was dropped and spin-coated to form an insulation layer. Under this condition, the thickness of the compound (1-1-26) was 25 nm and the thickness of the insulation layer was 300 nm. On the insulation layer, chromium and aluminum were vapor-deposited in this order using a shadow mask to provide a gate electrode, obtaining an organic transistor as shown in FIG. 2. Under this condition, the thickness of the chromium layer was 5 nm and the thickness of the aluminum layer was 200 nm.

Next, the electric property of the resultant organic transistor was measured. It could be confirmed that the organic transistor having the film of the compound (1-1-26) as an organic semiconductor layer was a p-type organic transistor. Further, the carrier saturated electric field effect mobility μ of the organic transistor was calculated using the formula representing the drain current Id in a saturated region of the electric property of the organic transistor.

Id=(W/2L)μCi(Vg−Vt)² (a)

Here, L and W represent the gate length and the gate width of the organic transistor, respectively, Ci represents the capacity per unit area of the gate insulation film, Vg represents the gate voltage, and Vt represents the threshold voltage of the gate voltage. The carrier mobility μ of the organic transistor having the produced film as an organic semiconductor layer was calculated using the formula (a), to find that the carrier mobility was 0.25 (cm²/V·s).

### INDUSTRIAL APPLICABILITY

The present invention provides an organic semiconductor device having high carrier mobility, a film contained in the device, and a compound contained in the film.

1. A dichalcogenobenzodipyrrole compound represented by the formula (1): 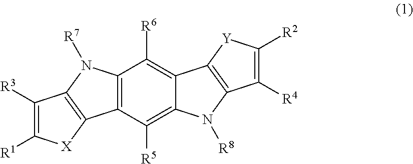
wherein, X and Y represent each independently a sulfur atom, an oxygen atom, a selenium atom, a tellurium atom or SO₂; R¹ to R⁸ represent each independently a hydrogen atom, a halogen atom, an alkyl group having 1 to 30 carbon atoms optionally substituted by a fluorine atom, an alkoxy group having 1 to 30 carbon atoms optionally substituted by a fluorine atom, an alkenyl group having 2 to 30 carbon atoms optionally substituted by a fluorine atom, an alkynyl group having 2 to 30 carbon atoms optionally substituted by a fluorine atom, an alkylthio group having 1 to 30 carbon atoms optionally substituted by a fluorine atom, an aryl group having 6 to 30 carbon atoms or a heteroaryl group having 4 to 30 carbon atoms; the aryl group and the heteroaryl group may have at least one selected from the group consisting of a fluorine atom, alkyl groups optionally substituted by a fluorine atom, alkoxy groups optionally substituted by a fluorine atom, alkenyl groups optionally substituted by a fluorine atom, alkynyl groups optionally substituted by a fluorine atom and alkylthio groups optionally substituted by a fluorine atom.

2. The dichalcogenobenzodipyrrole compound according to claim 1, wherein X and Y are a sulfur atom in said formula (1).

3. The dichalcogenobenzodipyrrole compound according to claim 1, wherein R³ and R⁴ are a hydrogen atom or a halogen atom and R⁷ and R⁸ are an alkyl group having 1 to 30 carbon atoms, an aryl group having 7 to 30 carbon atoms or a heteroaryl group having 5 to 30 carbon atoms, wherein the aryl group and the heteroaryl group have an alkyl group optionally substituted by a fluorine atom or an alkoxy group optionally substituted by a fluorine atom in said formula (1).

4. The dichalcogenobenzodipyrrole compound according to claim 1, wherein R⁵ and R⁶ are a hydrogen atom in said formula (1).

5. The dichalcogenobenzodipyrrole compound according to claim 1, wherein R¹ to R⁴ are a hydrogen atom or a halogen atom in said formula (1).

6. The dichalcogenobenzodipyrrole compound according to claim 1, wherein R⁷ and R⁸ are an aryl group having 7 to 26 carbon atoms having an alkyl group optionally substituted by a fluorine atom in said formula (1).

7. The dichalcogenobenzodipyrrole compound according to claim 1, wherein R⁷ and R⁸ are an alkyl group having 1 to 20 carbon atoms optionally having a fluorine atom in said formula (1).

8. A film containing the dichalcogenobenzodipyrrole compound according to claim 1.

9. A film composed of the dichalcogenobenzodipyrrole compound according to claim 1.

10. An organic transistor containing the film according to claim 8.

11. An organic semiconductor device containing the film according to claim 8.

12. A process comprising a step of reacting a compound represented by the formula (2): 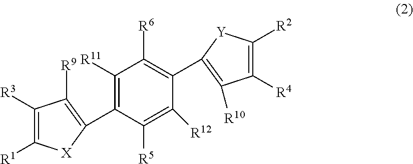
wherein, X and Y represent each independently a sulfur atom, an oxygen atom, a selenium atom, a tellurium atom or SO₂; R¹ to R⁶ represent each independently a hydrogen atom, a halogen atom, an alkyl group having 1 to 30 carbon atoms optionally substituted by a fluorine atom, an alkoxy group having 1 to 30 carbon atoms optionally substituted by a fluorine atom, an alkenyl group having 2 to 30 carbon atoms optionally substituted by a fluorine atom, an alkynyl group having 2 to 30 carbon atoms optionally substituted by a fluorine atom, an alkylthio group having 1 to 30 carbon atoms optionally substituted by a fluorine atom, an aryl group having 6 to 30 carbon atoms or a heteroaryl group having 4 to 30 carbon atoms; the aryl group and the heteroaryl group may have at least one selected from the group consisting of a fluorine atom, alkyl groups optionally substituted by a fluorine atom, alkoxy groups optionally substituted by a fluorine atom, alkenyl groups optionally substituted by a fluorine atom, alkynyl groups optionally substituted by a fluorine atom and alkylthio groups optionally substituted by a fluorine atom; R⁹ to R¹² represent each independently a halogen atom;
and an amine compound represented by the formula (3):
R⁷—NH₂ (3)
wherein, R⁷ represents a hydrogen atom, a halogen atom, an alkyl group having 1 to 30 carbon atoms optionally substituted by a fluorine atom, an alkoxy group having 1 to 30 carbon atoms optionally substituted by a fluorine atom, an alkenyl group having 2 to 30 carbon atoms optionally substituted by a fluorine atom, an alkynyl group having 2 to 30 carbon atoms optionally substituted by a fluorine atom, an alkylthio group having 1 to 30 carbon atoms optionally substituted by a fluorine atom, an aryl group having 6 to 30 carbon atoms or a heteroaryl group having 4 to 30 carbon atoms; the aryl group and the heteroaryl group may have at least one selected from the group consisting of a fluorine atom, alkyl groups optionally substituted by a fluorine atom, alkoxy groups optionally substituted by a fluorine atom, alkenyl groups optionally substituted by a fluorine atom, alkynyl groups optionally substituted by a fluorine atom and alkylthio groups optionally substituted by a fluorine atom;
to produce a dichalcogenobenzodipyrrole compound represented by the formula (1′): 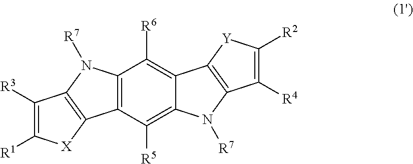
wherein, X, Y, R¹ to R⁷ are as described above.

13. A composition containing the dichalcogenobenzodipyrrole compound according to claim 1 and an organic solvent.

14. A process for producing a film, comprising a step of coating the composition according to claim 13 on a substrate or an insulation layer and a step of drying the coated film coated on the substrate or insulation layer.
